(19) United States
(12) Patent Application Publication
(10) Pub. No.: US 2026/0005141 A1
(43) Pub. Date: Jan. 1, 2026

(54) OPTIMIZED 3D INTEGRATED BACKSIDE POWER DELIVERY STRUCTURE

(71) Applicant: International Business Machines Corporation, Armonk, NY (US)

(72) Inventors: Qianwen Chen, Chappaqua, NY (US); Joshua M. Rubin, Albany, NY (US); Ruilong Xie, Niskayuna, NY (US); Tao Li, Slingerlands, NY (US)

(21) Appl. No.: 18/755,180

(22) Filed: Jun. 26, 2024

(51) Int. Cl. H01L 23/528; H01L 23/373; H01L 25/065

(52) U.S. Cl. CPC H01L 23/5286; H01L 23/3736; H01L 23/5283; H01L 25/0657; H01L 2225/06513

(57) ABSTRACT

An exemplary stacked semiconductor structure includes a first integrated device structure having a first frontside and a first backside in which the first backside comprises a first backside power distribution network, a seconded integrated device structure having a second frontside and a second backside in which the second backside comprises a second backside power distribution network, a plurality of hybrid bond connections between the first frontside and the second frontside, at least one first power bump on the first frontside configured to deliver power to the first backside power distribution network, and at least one second power bump on the second backside configured to deliver power to the second backside power distribution network.

### BACKGROUND

The present invention relates generally to the electrical, electronic and computer arts and, more particularly, to techniques for incorporating backside power delivery to three dimensional (3D) stacked dies and the like.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. Scaling efforts have greatly increased the number of transistors per unit area in 2D circuits, which has enabled the integration of heterogeneous functional circuits, such as logic and memory circuits, onto the same semiconductor substrate. However, 2D scaling efforts are running into greater challenges as scaling enters single digit nanometer semiconductor device fabrication nodes.

Semiconductor device fabricators have expressed a desire for three-dimensional (3D) semiconductor circuits in which transistors are stacked on top of each other as another means of further scaling of integrated circuits (ICs). Transistors can be stacked within a die, or several dies can be stacked. In addition, backside power distribution networks (BSPDN) are very attractive schemes for future complementary metal oxide semiconductor (CMOS) scaling. However, incorporating effective 3D die stacking a power delivery is challenging.

### BRIEF SUMMARY

Principles of the invention provide techniques for incorporating backside power delivery to three dimensional (3D) stacked devices and the like. In one aspect, an exemplary stacked semiconductor structure includes a first integrated device structure having a first frontside and a first backside in which the first backside has a first backside power distribution network, a seconded integrated device structure having a second frontside and a second backside in which the second backside comprises a second backside power distribution network, a plurality of hybrid bond connections between the first frontside and the second frontside, at least one first power bump on the first frontside configured to deliver power to the first backside power distribution network, and at least one second power bump on the second backside configured to deliver power to the second backside power distribution network.

In another aspect, an exemplary method of forming a stacked semiconductor structure includes providing a first integrated device structure having a first frontside and a first backside in which the first backside has a first power distribution network, providing a second integrated device structure having a second frontside and a second backside in which the second backside has a second power distribution network; hybrid bonding the first frontside and the second frontside to form a stacked structure, forming at least one first power bump directly on the first frontside configured to deliver power to the first backside power distribution network, and forming at least one second power bump on the second backside configured to deliver power to the second backside power distribution network. The first backside further includes a heat metallic distribution structure and a dielectric having a thermal conductivity greater than the thermal conductivity of silicon dioxide.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 lists exemplary steps of a method of making a stacked semiconductor in accordance with aspects of the invention; and

FIGS. 2-10 depict exemplary cross-sections of a stacked semiconductor structure at various points in the steps of the method of FIG. 1 in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Typically, when two die are vertically attached to each other both power delivery to a first-die and high-speed signal input/output (I/O) communication between first and second die are through fine-pitch bonding pads at the attachment interface. The proximity of the power delivery lines to the signal delivery lines causes unwanted electrical interference. Inserting thick power distribution layer in the first die's back end of line (BEOL) will limit IO density. Thus, the first die has competition of resources for signal and power using a standard techniques.

However, techniques as disclosed herein can provide substantial beneficial technical effects. Some embodiments may not have these potential advantages and these potential advantages are not necessarily required of all embodiments. By way of example only and without limitation, one or more embodiments may provide one or more of:
Separating power delivery and signal communication to the first die by using different path thereby minimizing noise coupling between power and signal between different layers of dies;
Separating power delivery and signal communication to the first die by using different paths, specifically routing power distribution on the backside of the first die, thereby eliminating the need for a power distribution layer, which are typically very large (“fat wires”), in the first die's BEOL which would otherwise limit I/O density. The presence of fat wires would limit the signal routing and the ability to pass many signals through a hybrid-bonded interface.
Provides face to face (F2F) hybrid bonding for high-speed signal I/O between first and second dies while using perimeter solder bumps of the first die face to deliver power to the first die (1) thereby enabling independent power delivery to both chips, (2) thereby minimizing signal interference between first and second dies of a stack, and (3) thereby reducing resource limitations/congestion for routing power for both dies and signal through the smaller die. Specifically, the power to the first die does not require the current to go through the second die. As a result, the second die of the stack does not have to support the power distribution for both itself and the first die. This configuration avoids additional power connections (bumps) between the second die and a laminate/interposer which means the area of the second die can potentially be reduced. High aspect ratio through silicon vias (TSVs) through an integrated device structure are not required.

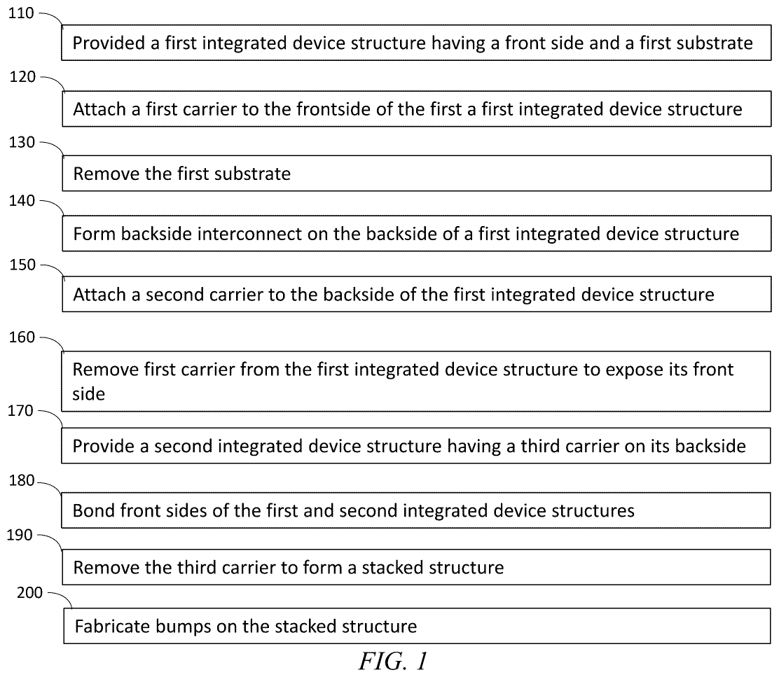

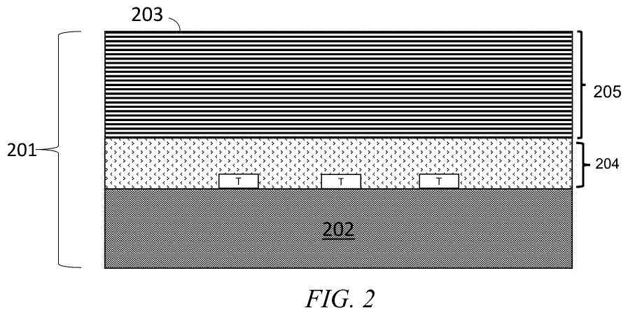

Aspects of the invention provide a stacked semiconductor structure including at least two face-to-face (F2F) hybrid-bonded integrated devices in which power is supplied to a backside power distribution network of a first integrated device by way of a frontside bump to the first integrated device. Referring to FIG. 1 steps of an exemplary method of making such a stacked semiconductor structure are listed. In step 110, provides a first integrated device structure 201. Referring to the cross-section of FIG. 2, the first integrated device structure 201 can include a first substrate 202, a first transistor level 204, a first backend of line (first BEOL 205). The first substrate 202 can be any semiconductor but is typically silicon or silicon on insulator. The first transistor level 204 includes a plurality of transistors “T” and contacts (not shown) surrounded by a dielectric. The first BEOL includes interconnection levels for wiring the transistors into circuits. A first frontside 203 of the device, is the side opposite the first substrate 202 or stated another way, the top of the first BEOL 205. The first integrated device structure 201 can be a die having a single chip or can include multiple chips, for example, a wafer.

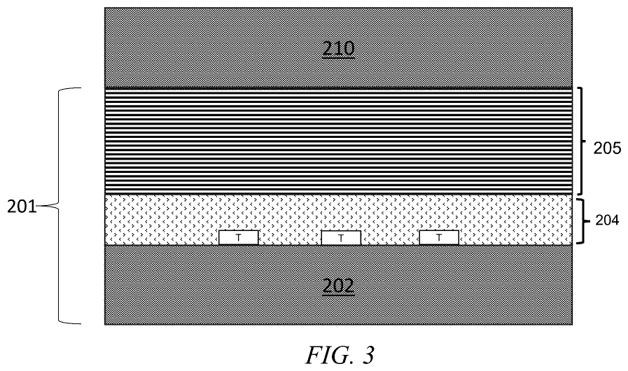

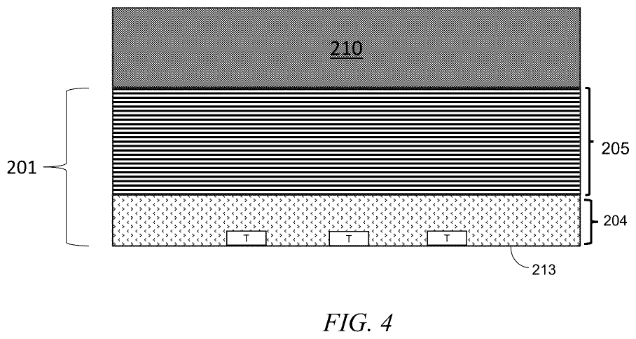

In step 120 of FIG. 1 and also referring to the FIG. 3 cross-section, a first carrier 210 is attached to the frontside 203 of the first a first integrated device structure 201. The first carrier 210 can be silicon or other suitable material and is attached via a release layer (not shown) between the first carrier 210 and the first frontside 203. Upon attaching the first carrier, the first substrate 202 is removed in step 130 to expose the first backside 213 of the first integrated device structure 201 (see FIG. 4).

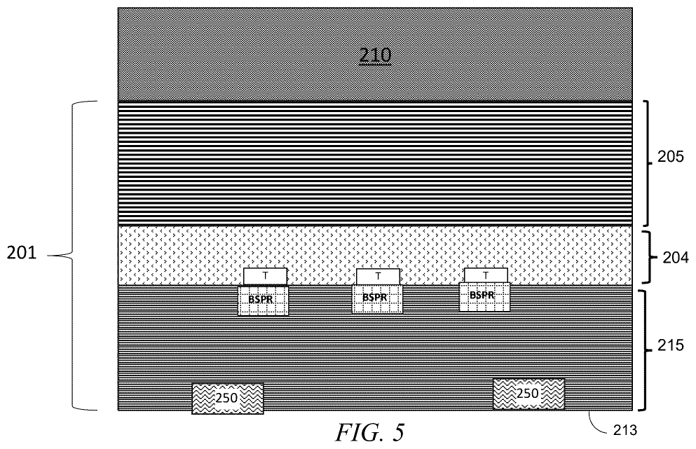

In step 140 of FIG. 1 and also referring to the FIG. 5 cross-section, a first backside interconnect 215 level is formed on the backside 213 of the first a first integrated device structure 201. The first backside interconnect 215 level is similar to the BEOL 205 of the first frontside 203. The first backside interconnect 215 level also include a backside power distribution network which includes a backside power rail (BSPR) electrically connected to the transistors T of the transistor level 204. The first backside interconnect 215 level also include a heat distribution structure 250 which can be a metallic structure. In the figures, the heat distribution structure 250 is shown generically, but can include via and line stacked structures that pass through the first backside interconnect 215 level to enable direct thermal paths from the transistors. The heat distribution structure 250 can be formed while forming the first backside interconnect 215 level or they could be formed afterwards, for example, by patterning a large via or the like. To further aid in heat distribution away from the transistor level 204, one or more dielectrics in the first backside interconnect 215 level can be high thermal conductivity dielectrics. Here, high thermal conductivity dielectrics include insulating materials with a thermal conductivity greater than the thermal conductivity of silicon dioxide such as one or more of silicon nitride, aluminum nitride, hexagonal boron nitride, and nanocomposites. After forming the first backside interconnect 215 level, the first integrated device structure 201 now includes the first backside interconnect 215 level, the first transistor level 204, and the first BEOL 205. Now, the first backside 213 is considered to be the bottom of the first backside interconnect 215 level.

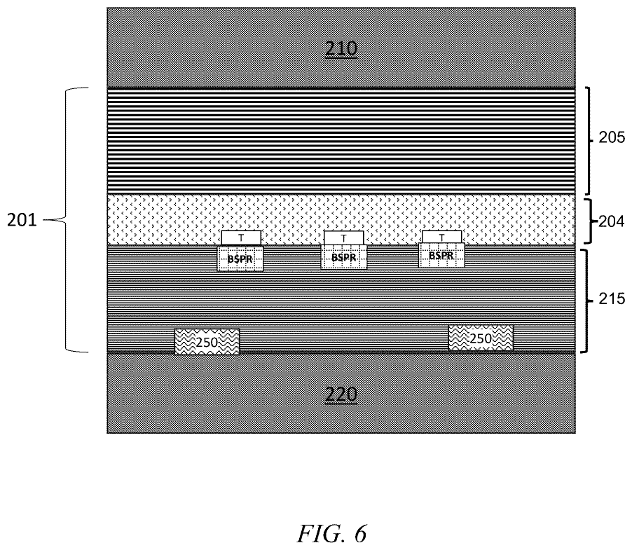

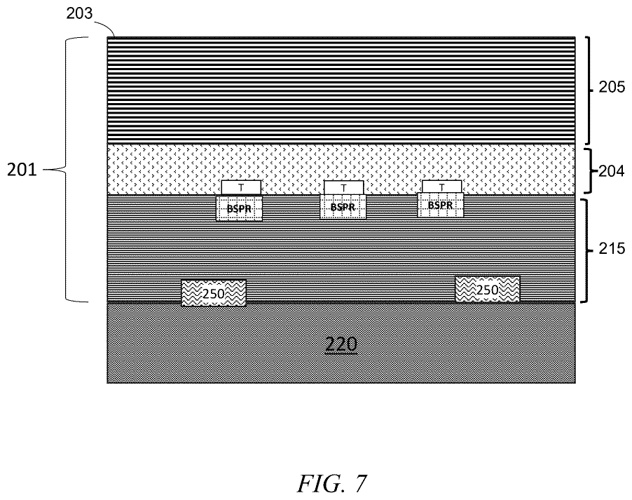

In step 150 of FIG. 1 and referring to the FIG. 6 cross-section, a second carrier 220 is attached to the first backside 213 of the first integrated device structure 201. In step 160 of FIG. 1 and referring to the FIG. 7 cross-section, the carrier 210 is removed from the first frontside 203 of the first integrated device structure 201.

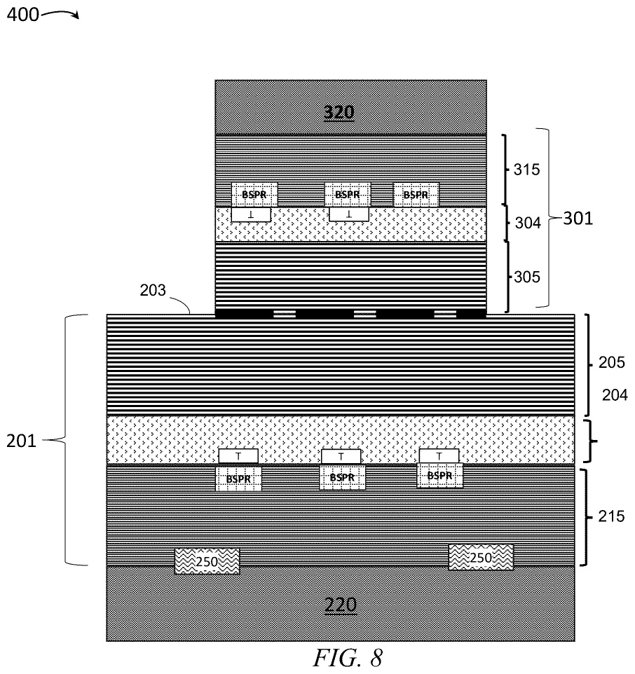

In steps 170 and 180 of FIG. 1 and referring to the FIG. 8 cross-section, a second integrated device 301 having a third carrier 320 on its backside is face to face hybrid bonded to the first integrated device 201 to form a stacked semiconductor structure 400. Face-to-face bonding means the frontsides of each device are facing each other and bonded together. Hybrid bonding means that each of the frontsides has conductor areas and insulator areas on their surfaces and these areas are bonded to each other (i.e. conductor of first frontside to conductor of second front side and insulator of first frontside to insulator of second front side) within alignment tolerances. In FIG. 8, a hybrid bonding interface is indicated by the horizontal dashed line between the first integrated device 201 and the second integrated device 301. Much like the first integrated device 201, the second integrated device 301 can have a second BEOL 305 level, a second transistor 304 level and a backside interconnect 305 level with second BSPR. The second integrated device 301 is not as wide as the first integrated device 201. While not denoted in the figures, the second integrated device 301 can also have device areas and non-device areas. The third carrier 320 can be as described for the first and second carrier.

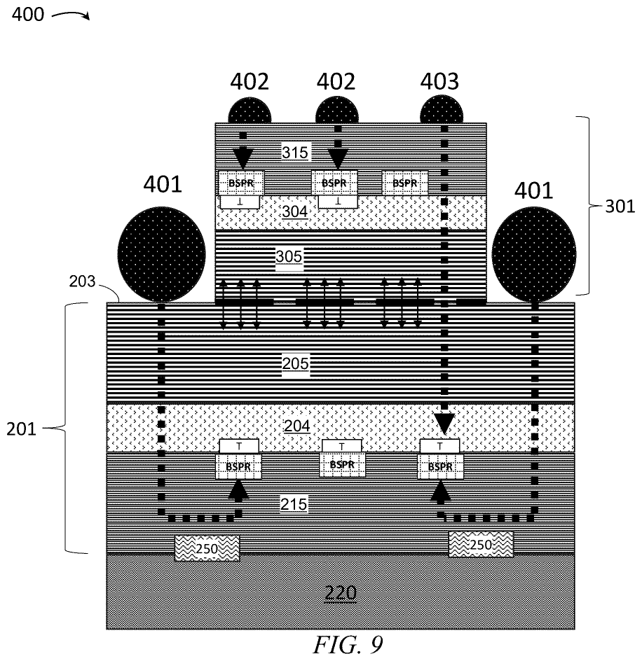

In steps 190 and 200 of FIG. 1 and referring to the FIG. 9 cross-section, the third carrier 320 is removed from the backside of the second integrated device 301 and a series of bumps are formed on both the first and second integrated devices. Referring to FIG. 9 first power bumps 401 are formed directly on the frontside 203 of the first integrated device 201. As indicated by the dashed arrow leading from the first power bumps 401 to the first BSPR in the backside interconnect 215 level of the first integrated device 201, the first power bump 401 delivers power to the backside power distribution network. The first integrated device 201 may receive some or all its power through the backside power distribution network. The power delivery path from the frontside 203 of the first integrated device 203 to the first BSPR can be cooled by the heat dissipators 250 in the first backside interconnect level 215 and by the use of high thermal conductivity dielectrics. As used herein, “bumps” include soldered structures and pillars or the like and any pad levels typically accompanying such structures, and as used herein “bumps” can include structures suitable for hybrid bonding to another semiconductor structure. Continuing with FIG. 9, another series of bumps are formed on the backside interconnect 315 level of the second integrated device 301. These bumps on the second integrated device 301 can have different functions from each other. For example, second power bumps 402 can deliver power to the backside power distribution network of the second integrated device 301. Meanwhile, third bump 403 reaches through the second integrated device 301 and into the first integrated device 201. In some embodiments third bump 403 can be a signal input/out bump which enable communication between the described first and second chip stack and either another adjacent chip(s) or back to a host. There can be multiple chips (3D or 2D) on an interposer (silicon or laminate) and each chip must have some input/output (IO) to communicate with the outside world. These can be serial or parallel IOs. While in other embodiments third bump 403 can be a power delivery bump to the first integrated device 201.

The various bumps can be in different combinations to delivery different voltage supplies. By way of example, and not limitation, for a particular voltage supply (e.g., first voltage V1), the first integrated device 201 could have V1 provided solely through the first power bump 401 (perimeter bumps). In another scenario, V1 could be provided to the first integrated device 201 or it could have that supply provided through a combination of the first power bump 401 (perimeter bumps) and the third power bumps 403 of the second integrated device 301. In a further exemplary option, The first integrated device 201 can have V1 provided by the first power bump 401 (perimeter bumps) and second voltage supply V2 provided through the third bump 402 of the second integrated device 301.

The double headed arrows across the hybrid bonding interface of the two devices indicate high-speed (low latency) input/output communications between the first and second stacked die. In contrast, third bump 403 when acting as a signal input/out bump will have higher latency and higher power to enable communication over a longer distance. By way of example and not limitation, signal input/out bump 403 can receive data from a host and then the second integrated device structure 301 and the first integrated device structure 201 will operate on that data using the links (i.e. the double headed arrows representing IO at hybrid bond interface in FIG. 9) to produce an output and send it back to host via signal input/out bump 403.

Continuing with FIG. 9, the stacked semiconductor structure 400 is stepped. As a result, in the FIG. 9 embodiment, the bottom of the first power bumps 401 on the frontside 203 of the first integrated device 201 are not at the same level as those bumps (e.g. second power bumps 402 and signal I/O bump 403) on the backside of the second integrated device 301. As depicted in FIG. 9, the top of the bumps are also at different levels, however, it is contemplated that the tops first power bumps 401 and the tops of the bumps on the backside of the second integrated device 301 can be at the same height.

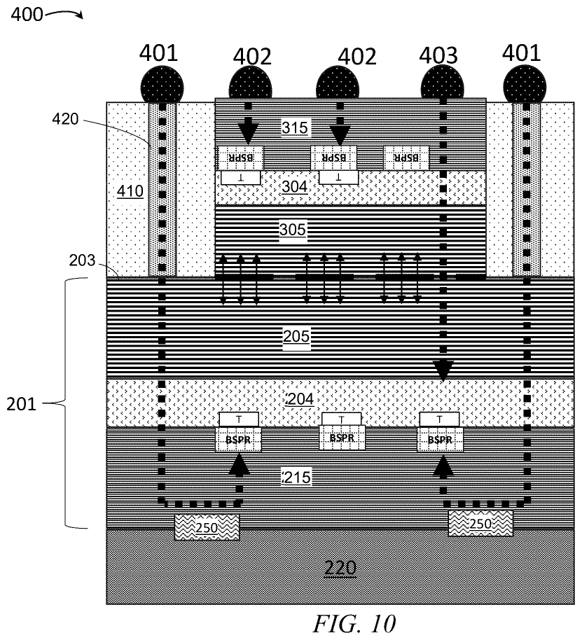

Turning to FIG. 10, the first power bumps 401 are still on the frontside 203 of the first integrated device 201, but there is a planarization layer 410 between the first power bump 401 and the first BEOL 205. The planarization layer 410 can act as a planarization layer between the frontside 203 of the first integrated device structure 201 and the backside interconnect 315 level of the second integrated device structure 301. The planarization layer 410 can comprise one or more layers. The planarization layer 410 can be either organic or inorganic dielectric. Therefore, it can be a molding compound or other polymer, or it can be one or more layers of silicon oxide, silicon nitride, or other dielectrics typically deposited via a chemical vapor deposition process including plasma processes or spin on dielectrics or the like. Optionally, a redistribution layer (RDL) can also be above planarization layer 410 and the backside interconnect 315 level of the second integrated device structure 301. A through via 420 electrically connects the first power bump 401 to the first BEOL 205 through the planarization layer 410. By passing through via 420 through the planarization layer 410, real estate is not used within the integrated device structures. Through via 420 could be formed as a pillar prior to planarization layer 410 formation or it could be formed after planarization layer 410 formation via a damascene process using a laser or reactive ion etching to form the opening in the planarization layer 410. The later method is preferred when there is a larger step height between the frontside 203 of the first integrated device structure 201 and the backside interconnect 315 level of the second integrated device structure 301. In the FIG. 10 embodiment, the bumps (i.e. first power bump 401, second power bump 402 and signal I/O bump 403) can be level at both the top and bottom of the bumps.

Referring to FIG. 10, the first integrated device structure 201 is shown in which the first integrated device structure 201 is wider than the second integrated device structure 301 which allows for portions of the first frontside 203 to be uncovered by the second integrated device structure 301. However, the two integrated device structures can be any width relative to each other, only the stacking must be such so there is a portion of at least one of the integrated device structures which is uncovered by the other. Therefore, in cases where the widths of the two integrated device structures are approximately the same width, the structures are offset (translated) from each other and each integrated device structure will have a bonding-side surface which is uncovered by the other integrated device structure. Even in cases in which the integrated device structures have different widths, the smaller structure does not have to be centered on the larger (as in FIG. 10) but here, too, the structures can be translated relative to each other so that one edge of each structure is aligned with each other, or structures can be translated relative to each other so that both structures will have a bonding-side surface which is uncovered by the other integrated device structure.

In summary, an exemplary stacked semiconductor 400 structure includes a first integrated device 201 structure having a first frontside 203 and a first backside 213 in which the first backside includes 213 a first backside power distribution network, a seconded integrated device 301 structure having a second frontside and a second backside wherein the second backside includes a second backside power distribution network, a plurality of hybrid bond connections between the first frontside 203 and the second frontside, at least one first power bump 401 on the first frontside 203 configured to deliver power to the first backside power distribution network, and at least one second power bump 402 on the second backside configured to deliver power to the second backside power distribution network.

In some embodiments, the stacked semiconductor 400 structure first backside further includes a heat distribution structure 250, stacked semiconductor 400 structure which can be metallic. An exemplary heat distribution structure 250 can include via and line stacked structures that pass through the first backside interconnect 215 level. In addition, the first backside power distribution network can include a high thermal conductivity dielectric which can include one or more of silicon nitride, aluminum nitride, hexagonal boron nitride, and nanocomposites. The stacked semiconductor structure of Claim 1 wherein the first power bump is directly on the first frontside.

In other embodiments, the at least one first power bump 401 on the first frontside 203 is configured to deliver all power to first integrated device structure 201 to the first backside power distribution network.

In a further aspect, the exemplary stacked semiconductor structure 400 can further include a third bump 403 on the second integrated device 301. Here, the first integrated device structure 201 can be configured to receive a first voltage (V1) from the at least one first power bump 401 and from the third bump 403.

In another aspect, the exemplary stacked semiconductor structure 400 can further include a third bump 403 on the second integrated device 301. Here, the first integrated device structure 201 can be configured to receive a first voltage (V1) from the at least one first power bump 401 and configured to receive a second voltage (V2) from the third bump 403.

In yet another aspect, the exemplary stacked semiconductor structure 400 can further include a third bump 403 on the second integrated device 301. Here, the first integrated device structure 201 can be configured to receive a first voltage (V1) only from one of the at least one first power bump 401 and configured to receive a second voltage (V2) from the first power bump 401 and the third bump 403.

In yet another aspect, the exemplary stacked semiconductor structure 400 can include a third bump 403 on the second integrated device 301. Here, the first integrated device structure 201 is configured to receive a first voltage (V1) only from third bump 403 and is configured to receive a second voltage (V2) from the first power bump 401 and the third bump 403.

In some instances, the first integrated device structure 201 can be wider than the second integrated device structure 301. In some instances, the first integrated device structure 201 can be a wafer. In some instances, the second integrated device structure 301 is centered on the first integrated device structure 201. In some instances, the second integrated device structure 301 can be wider than the first integrated device structure 201.

In another aspect, the first power bump 401 has a bottom that is at a same level a second power bump 402's bottom. While in other embodiments, the bottom of the first power bump 401 is at a different level from that of the second power bump 402.

Furthermore, the stacked semiconductor structure 400 can include at least one signal input/out bump (here, third bump 403) on the second backside.

In another aspect, an exemplary method of forming a semiconductor structure includes providing a first integrated device structure 201 having a first frontside 203 and a first backside having, the first backside having a first power distribution network and also providing a second integrated device structure 301 having a second frontside and a second backside wherein the second backside includes a second power distribution network. The two frontside are hybrid bonded together to form a stacked semiconductor structure 400. At least one first power bump 401 is formed directly on the first frontside 203 and is configured to deliver power to the first backside power distribution network. At least one second power bump 402 is formed on the second backside and is configured to deliver power to the second backside power distribution network. The first backside further comprises a metallic heat distribution structure 250 and a dielectric having a thermal conductivity greater than the thermal conductivity of silicon dioxide.

Bumps include soldered structures and pillars or the like and any pad levels typically accompanying such structures such as RDL.

Silicon, doped silicon and silicon germanium are a non-limiting example of a suitable semiconductor material, other materials are also possible. Active areas, including channel and source drain regions include semiconductor material.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A stacked semiconductor structure comprising:
a first integrated device structure having a first frontside and a first backside wherein the first backside comprises a first backside power distribution network;
a seconded integrated device structure having a second frontside and a second backside wherein the second backside comprises a second backside power distribution network;
a plurality of hybrid bond connections between the first frontside and the second frontside;
at least one first power bump on the first frontside configured to deliver power to the first backside power distribution network; and
at least one second power bump on the second backside configured to deliver power to the second backside power distribution network.

2. The stacked semiconductor structure of claim 1 wherein the first backside further comprises a heat distribution structure.

3. The stacked semiconductor structure of claim 2 wherein the heat distribution structure is metallic.

4. The stacked semiconductor structure of claim 2 wherein the heat distribution structure comprises via and line stacked structures that pass through the first backside interconnect level.

5. The stacked semiconductor structure of claim 1 wherein the first backside power distribution network comprises a high thermal conductivity dielectric.

6. The stacked semiconductor structure of claim 5 wherein the high thermal conductivity dielectric comprises one or more of silicon nitride, aluminum nitride, hexagonal boron nitride, and nanocomposites.

7. The stacked semiconductor structure of claim 1 wherein the first power bump is directly on the first frontside.

8. The stacked semiconductor structure of claim 1 wherein the at least one first power bump on the first frontside is configured to deliver all power to first integrated device structure to the first backside power distribution network.

9. The stacked semiconductor structure of claim 1 further comprising:
a third bump on the second integrated device; and
wherein the first integrated device structure is configured to receive a first voltage from the at least one first power bump and from the third bump.

10. The stacked semiconductor structure of claim 1 further comprising:
a third bump on the second integrated device;
wherein the first integrated device structure is configured to receive a first voltage from the at least one first power bump; and
wherein the first integrated device structure is configured to receive a second voltage from the third bump.

11. The stacked semiconductor structure of claim 1 further comprising:
a third bump on the second integrated device; and
wherein the first integrated device structure is configured to receive a first voltage only from one of the at least one first power bump;
wherein the first integrated device structure is configured to receive a second voltage from the first power bump and the third bump.

12. The stacked semiconductor structure of claim 1 further comprising:
a third bump on the second integrated device; and
wherein the first integrated device structure is configured to receive a first voltage only from third bump;
wherein the first integrated device structure is configured to receive a second voltage from the first power bump and the third bump.

13. The stacked semiconductor structure of claim 1 wherein the first integrated device structure is wider than the second integrated device structure.

14. The stacked semiconductor structure of claim 1 wherein the first integrated device is a wafer.

15. The stacked semiconductor structure of claim 1 wherein the second integrated device structure is wider than the first integrated device structure.

16. The stacked semiconductor structure of claim 15 wherein the second integrated device structure is centered on the first integrated device structure.

17. The stacked semiconductor structure of claim 1 wherein a first bottom of the first power bump is at a same level from a second bottom of the second power bump.

18. The stacked semiconductor structure of claim 1 wherein a first bottom of the first power bump is at a different level from a second bottom of the second power bump.

19. The stacked semiconductor structure of claim 1 further comprising at least one signal input/out bump on the second backside.

20. A method of forming a semiconductor structure, comprising:
providing a first integrated device structure having a first frontside and a first backside wherein the first backside comprises a first power distribution network;
providing a second integrated device structure having a second frontside and a second backside wherein the second backside comprises a second power distribution network; hybrid bonding the first frontside and the second frontside to form a stacked structure;
forming at least one first power bump directly on the first frontside configured to deliver power to the first backside power distribution network; and
forming at least one second power bump on the second backside configured to deliver power to the second backside power distribution network;
wherein the first backside further comprises a metallic heat distribution structure and a dielectric having a thermal conductivity greater than the thermal conductivity of silicon dioxide.
